(19) United States
(12) Patent Application Publication
(10) Pub. No.: US 2016/0056094 A1
(43) Pub. Date: Feb. 25, 2016

(54) BALL GRID ARRAY PACKAGE WITH MORE SIGNAL ROUTING STRUCTURES

(71) Applicants: KESVAKUMAR V.C. MUNIANDY, Klang (MY); Navas Khan Oratti Kalandar, Austin, TX (US)

(72) Inventors: KESVAKUMAR V.C. MUNIANDY, Klang (MY); Navas Khan Oratti Kalandar, Austin, TX (US)

(73) Assignee: Freescale Semiconductor, Inc., Austin, TX (US)

(21) Appl. No.: 14/463,651

(22) Filed: Aug. 19, 2014

(51) Int. Cl. H01L 23/495; H01L 21/56; H01L 21/48

(52) U.S. Cl. CPC H01L 23/49541; H01L 23/4952; H01L 23/49568; H01L 21/4825; H01L 21/56; H01L 21/4828; H01L 21/4803; H01L 21/4871

(57) ABSTRACT

A semiconductor package includes a substrate, a die mounted on a first side of the substrate, an array of solder balls mounted on a second, opposite side of the substrate, and a signal-routing structure mounted on the first side of the substrate and adjacent to the die. The substrate and the signal-routing structure provide electrical connections between die pads on the die and some of the solder balls.

### BACKGROUND OF THE INVENTION

The present invention relates generally to semiconductor packaging and, more particularly, to ball grid array (BGA) packages.

Certain semiconductor packages, such as BGA packages, include an integrated circuit (IC or “chip”) die or other active component electrically coupled to a plurality of solder balls via a substrate. The substrate comprises one or more interconnected, patterned metal layers sandwiched between insulating layers, which electrically connect die pads on the die to respective solder balls on the exterior of the package. The die is encapsulated by a mold compound to protect the die from environmental contaminants. The balls serve as input and output (I/O) connections to the encapsulated IC die and are typically arranged in rows and columns on the bottom of the BGA package.

Compared to other types of semiconductor packages, BGA packages can advantageously provide a larger number of electrical connections than other types of packages, such as quad flat no lead (QFN) packages, and are therefore widely used for dies requiring many I/O connections, such as high-performance microprocessors, large field-programmable gate arrays, or the like.

One typical BGA package design has the die encapsulated in molding compound (referred to herein as an overmold) and attached to one side of a hard substrate consisting of a planar laminate substrate containing the interconnected patterned metal layers. On the other side of the substrate, there is a grid of connection pads to which the solder balls are attached for mounting the packaged device on a circuit board. However, the resulting package (i) is relatively thick because of the incorporated substrate and (ii) has lateral dimensions driven by the need to space the solder balls apart (increasing ball-to-ball pitch) to provide room for multiple conductor traces in the substrate and disposed between the solder balls. Because the traces are for routing signals between the solder balls and the die pads on the chip, the greater the number of I/O connections needed by the chip, the greater the pitch to accommodate the increased number of traces.

Another typical BGA package dispenses with the hard substrate and instead layers the overmolded die with alternating layers of a flexible insulating layers and patterned metal conductor layers to achieve the function of the substrate. With either approach, the finished package is thicker and has a larger lateral dimensions than might be desired.

Accordingly, it would be advantageous to have a BGA package that can be thinner and have smaller lateral dimensions than conventional BGA packages.

### BRIEF DESCRIPTION OF THE DRAWINGS

Embodiments of the present invention are illustrated by way of example and are not limited by the accompanying figures, in which like references indicate similar elements. Elements in the figures are illustrated for simplicity and clarity and have not been drawn to scale. For example, the thicknesses of layers and regions may be exaggerated for clarity.

FIG. 1 shows a simplified top or plan view of a ball grid array (BGA) package consistent with one embodiment of the present invention;

FIG. 2 is a cross-sectional side view of the BGA package of FIG. 1;

FIG. 3 is a bottom view of the BGA package of FIG. 1;

FIGS. 4A and 4B show an “X-ray” top view and cross-sectional side view, respectively, of a portion of a signal-routing structure used in the BGA package of FIG. 1;

FIG. 5 is a flow chart showing an example of an assembly process for fabricating a BGA package consistent with embodiments of the invention, such as the BGA package of FIG. 1;

FIG. 6 is a cross-sectional side view of the BGA package of FIG. 1 at an intermediate step in the process of FIG. 5;

FIG. 7 is a cross-sectional side view of the BGA package of FIG. 1 at a different intermediate step in the process of FIG. 5; and

FIG. 8 is a cross-sectional side view of an alternative embodiment of the BGA package of FIG. 1.

### DETAILED DESCRIPTION OF THE INVENTION

Detailed illustrative embodiments of the present invention are disclosed herein. However, specific structural and functional details disclosed herein are merely representative for purposes of describing example embodiments of the present invention. Embodiments of the present invention may be embodied in many alternative forms and should not be construed as limited to only the embodiments set forth herein. Further, the terminology used herein is for the purpose of describing particular embodiments only and is not intended to be limiting of example embodiments of the invention.

As used herein, the singular forms “a”, “an”, and “the”, are intended to include the plural forms as well, unless the context clearly indicates otherwise. It further will be understood that the terms “comprises”, “comprising”, “has”, “having”, “includes”, or “including” specify the presence of stated features, steps, or components, but do not preclude the presence or addition of one or more other features, steps, or components. It also should be noted that, in some alternative implementations, the functions/acts noted may occur out of the order noted in the figures. For example, two figures shown in succession may in fact be executed substantially concurrently or may sometimes be executed in the reverse order, depending upon the functionality/acts involved. Further, the term “or” is to be interpreted as inclusive unless stated otherwise.

One embodiment of the invention is a ball grid array package, and another embodiment is a method for manufacturing a ball grid array package.

In one embodiment, a semiconductor package includes a substrate, a die mounted on a first side of the substrate, an array of solder balls mounted on a second side of the substrate, and a signal-routing structure mounted on the first side of the substrate and adjacent to the die. The substrate and the signal-routing structure provide electrical connections between die pads on the die and some of the solder balls.

In another embodiment, a method for manufacturing a semiconductor package, the method includes: a) forming a signal-routing structure having first and second sets of contact pads on a first surface thereof, the first set of contact pads electrically interconnected to corresponding pads of the second set of contact pads; b) mounting, on a base, a semiconductor die having first and second sets of die pads on a front side thereof such that the front side faces the base; c) mounting, on the base, the signal-routing structure adjacent the semiconductor die such that the first surface of the signal-routing structure faces the substrate; d) encapsulating the signal-routing structure and the semiconductor die; e) detaching the encapsulated die and signal-routing structure from the base, thereby exposing the front side of the die and the first surface of the signal-routing structure; and f) forming a substrate on the exposed front side of the die and the first surface of the signal-routing structure.

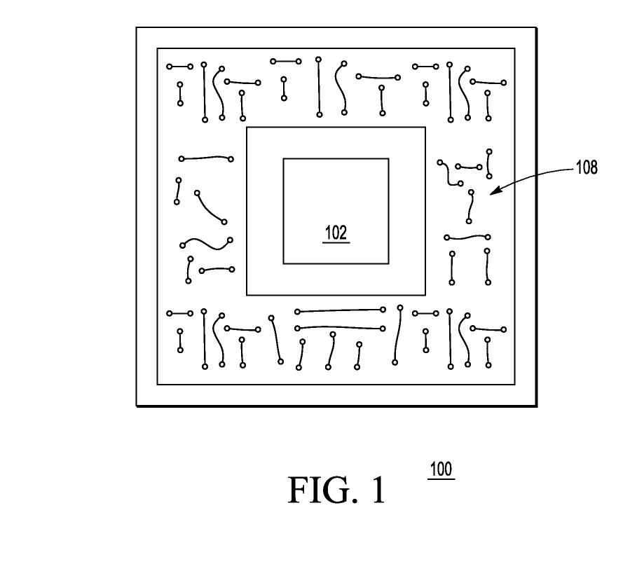

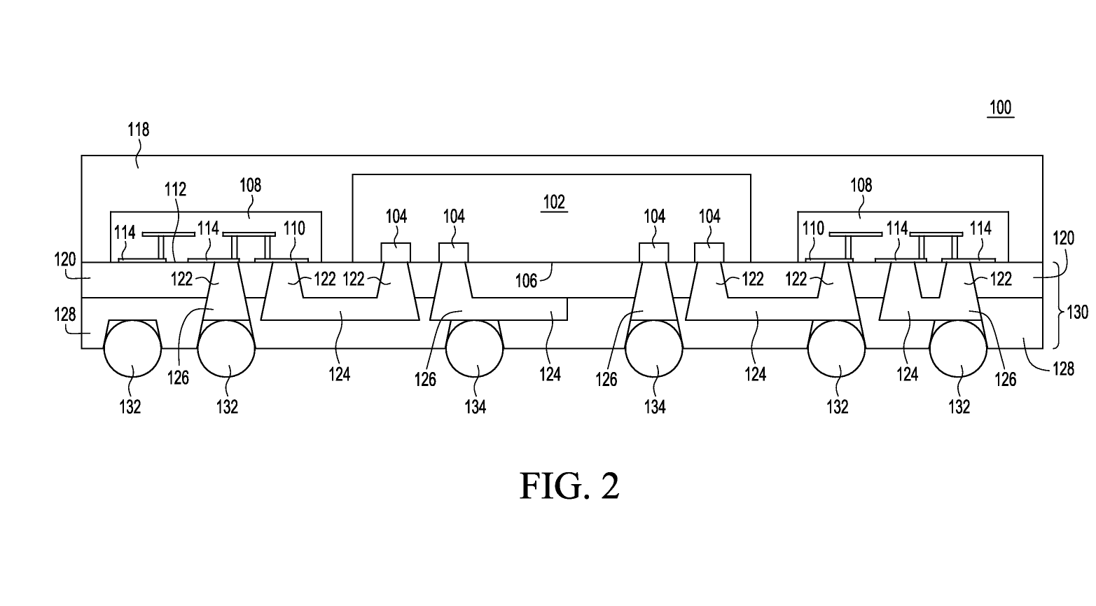

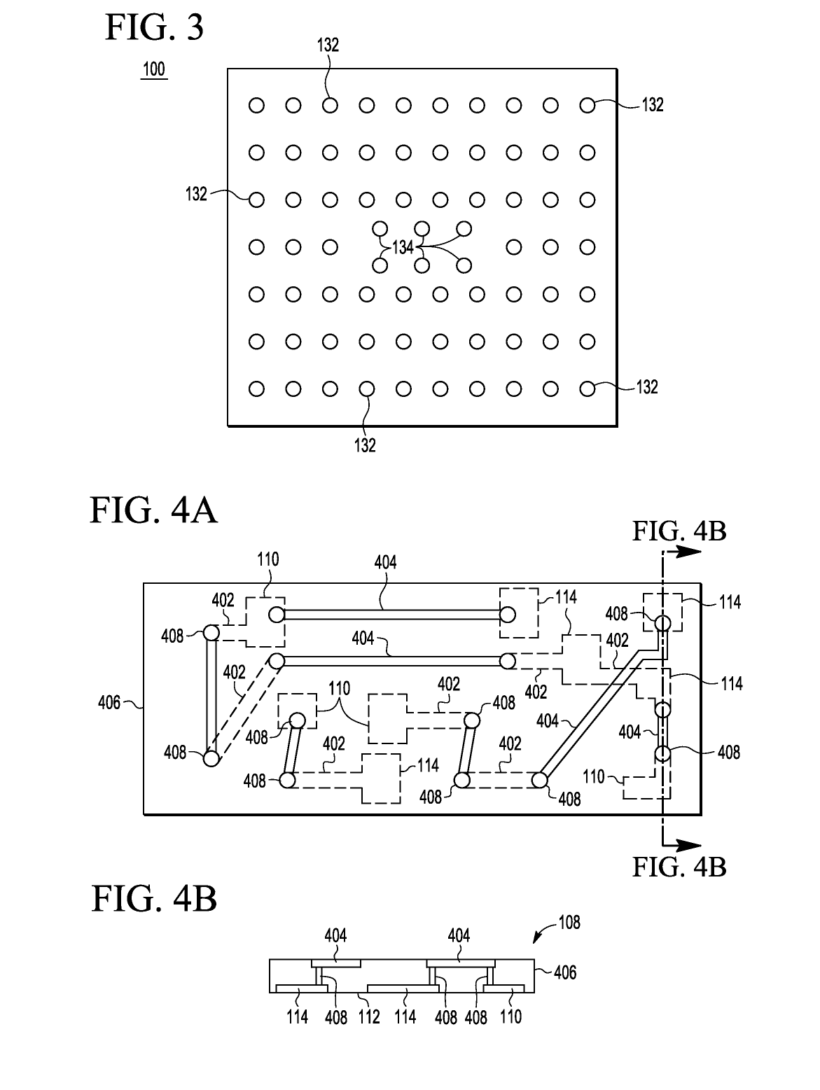

FIG. 1 shows a simplified top or plan view of a ball grid array (BGA) type semiconductor package 100 consistent with one embodiment of the invention, FIG. 2 shows a side cross-sectional view of the package 100 of FIG. 1, and FIG. 3 is a bottom view of the package 100 of FIG. 1. It is noted that alternative embodiments are not limited to BGA packages, but can be implemented for other package types, such as (without limitation), quad flat no lead (QFN) packages, packages, molded array packages (MAP), and quad flat pack (QFP) or other leaded packages where routing of signals from a semiconductor die to external connections of the package are needed.

The package 100 comprises a conventional semiconductor device or die 102 having multiple die pads 104 on a front side 106 of the die 102, which die pads are used to conduct signals to and from components, such as transistors (not shown), within the die 102. Such signals include, but are not limited to, digital signals, analog signals, and power supply signals needed for the components in the die to operate. Disposed adjacent to the die 102 is a signal-routing structure 108 that surrounds the die 102. In an alternative embodiment, there are one or more signal-routing structures 108 adjacent the sides of the die 102. As will be described in more detail below, the signal-routing structure 108 serves to route signals between terminals (e.g., balls 132) on the exterior of the package 100 and the die 102. A signal-routing structure 108 is, in one embodiment, a multi-layered structure with one or more wiring layers allowing signals applied to a first set of contact pads 110 on a front surface 112 of the structure 108 to be routed to a second set of contact pads 114 on the front surface 112. In one embodiment, the die pads 104 are connected to the first set of contact pads 110, and the second set of contact pads 114 are connected to the balls 132. Details on the signal-routing structure 108 are described in more detail below in connection with FIGS. 4a and 4b.

As shown in FIG. 2, over the die 102 and structure 108 is an overmold 118 of an encapsulant such as epoxy or the like. For clarity, the overmold is not shown in FIG. 1. The overmold serves to protect the die 102 and structure 108 from environmental hazards, such as moisture and dirt, and to provide mechanical rigidity to the package 100. For purposes here, the lateral dimensions of the package 100 are defined by the extent of the overmold 118. However, it is understood that other features, such as a substrate 130, might define the lateral dimensions of the package 100 where the overmold 118 does not extend to all edges of the substrate.

A dielectric layer 120 covers the front side 106 of the die 102 and the front surface 112 of the signal-routing structure 108 as well as exposed portions of the overmold 118 between the die and the signal-routing structure and the edges of the package 100. Here, the die's front side 106 and each signal-routing structure's front surface 112 are substantially coplanar. Conductive vertical vias 122 in the dielectric layer 120 connect certain contact pads 110, 114 on the signal-routing structure 108 and certain die pads 104 on the die 102 either directly to certain solder balls 132, 134 or to horizontal traces 124 on the bottom surface of the dielectric layer 120, some of which are in turn connected to solder balls or other vertical vias in the dielectric layer 120. Some of the vertical vias 122 and horizontal traces 124, typically formed from copper or a copper alloy, also form connection pads 126 onto which balls 132, 134 are attached.

Covering the traces 124 is a solder mask 128 having openings therein exposing the connection pads 126. The dielectric layer 120 and solder mask 128 may be formed of flexible polymers, such as polyimide, polybenzoxazole (PBO), or another similar insulating material. The dielectric layer 120, vias 122, traces 124, pads 126, and mask 128 form a substrate 130. Solder balls 132, 134 are formed from a lead (e.g., a lead-tin alloy) or lead-free (e.g., a tin-silver alloy) metal compound to provide electrical and mechanical connections between the package 100 and a circuit board or substrate in a computer, smartphone, or the like. In an alternative embodiment, multiple conductor and dielectric layers might be used to achieve more flexibility in signal routing.

Note that, in this embodiment, one of the traces 124 near the center of the illustration is shown not connecting to a ball or to a via. In this instance, the trace 124 might connect to balls or other vias 122 hidden in this cross-sectional side view. Further, solder ball 132 on the extreme left side of the illustration is shown not attached to a connection. Here, too, the solder ball is attached to a via or connection pad that is hidden in this cross-sectional side view.

The bottom of the package 100 as shown in FIG. 3 illustrates a greatly simplified exemplary layout of the balls 132. In this example and in one embodiment, most of the balls 132 are placed around the periphery of the package 100 and under the signal-routing structure 108 (FIG. 1). These balls typically carry data signals, although they might be used for power and ground connections. The balls 134 located in the middle of the bottom of the package 100, are primarily for providing power and ground to the die 102 (FIG. 1) and as such are generally not connected to the signal-routing structure 108 but are connected by the traces 124 (FIG. 2) directly to the respective die pads 104 (FIG. 2). By having the balls 132 located under or near the signal-routing structure, the distance a signal travels between the balls 132 and the die pads can be short, which is advantageous for high-speed applications. Similarly, short connections between balls 134 and the die pads allow for low resistance and reactance interconnections between a power supply and the die 102. For a typical BGA package, there might be hundreds of balls 132 and tens of balls 134.

FIG. 4A is an “X-Ray” top view of a portion of the signal-routing structure 108 illustrating some details of the signal-routing structure 108 and FIG. 4B is a cross-sectional side view of the structure 108 along the dotted line in FIG. 4A. As discussed above, the signal-routing structure 108 is used to route signals between the balls 132 and the die pads 104. The signal-routing structure gives flexibility to the package designer to electrically interconnect the die 102 and the balls 132. The signal-routing structure 108 is similar to a permanently configured patch-panel or switchboard to route signals where needed. Further, if multiple dies 102 are packaged in a single BGA package, the signal-routing structure 108 might also be used to route signals between the dies.

FIG. 4A shows (i) first traces 402 as dotted outlines of a first wiring layer formed on the front surface 112 (FIG. 4B) and (ii) second traces 404 as solid outlines of a second wiring layer separated from the first wiring layer by an intervening dielectric layer 406 (FIG. 4B). As shown in FIG. 4B, conductive vias 408 interconnect the first and second traces through the dielectric layer 406. The first and second sets of contact pads 110, 114 are also formed from the first traces 402 as discussed above. In this embodiment, a portion of the first trace 402 in the middle of FIG. 4B is shown for signal routing and connects to a contact pad 114 shown in FIG. 4a but not shown in FIG. 4B.

The wiring-layer traces 402, 404 are typically formed from copper or a copper alloy, and the dielectric layer is typically formed from a flexible polymer, such as polyimide, PBO, or from a ridged material such as glass-epoxy, ceramic, or silicon. In an alternative embodiment, three or more wiring layers might be used, requiring two or more intervening dielectric layers.

The signal-routing structure 108 might be made in tape form of multiple such structures using conventional processes for making a flexible substrate (e.g., polyimide) with the traces thereon. The tape might be pre-cut or cut as needed during the manufacturing of the package 100 to singulate the structures 108 prior to placing them in the package 100.

Signals are routed from the die pads 104 to the balls 132 in at least three sets of connections: first from the die to the signal-routing structure 108, then within the signal-routing structure, and then from the signal-routing structure to the balls 132. Each of these connection sets can be used together to reduce the overall size of the package 100 so that it might have a smaller thickness and shorter lateral dimensions than a conventional BGA package that relies on multiple levels of dielectric layers 124 and conductive layers 126 to route signals. Further, the signal-routing structure 108 allow the package designer more options to route a signal from a given die pad to virtually any ball and, similarly, fewer restrictions can be placed on the chip (die) designer to have a signal available on certain die pads.

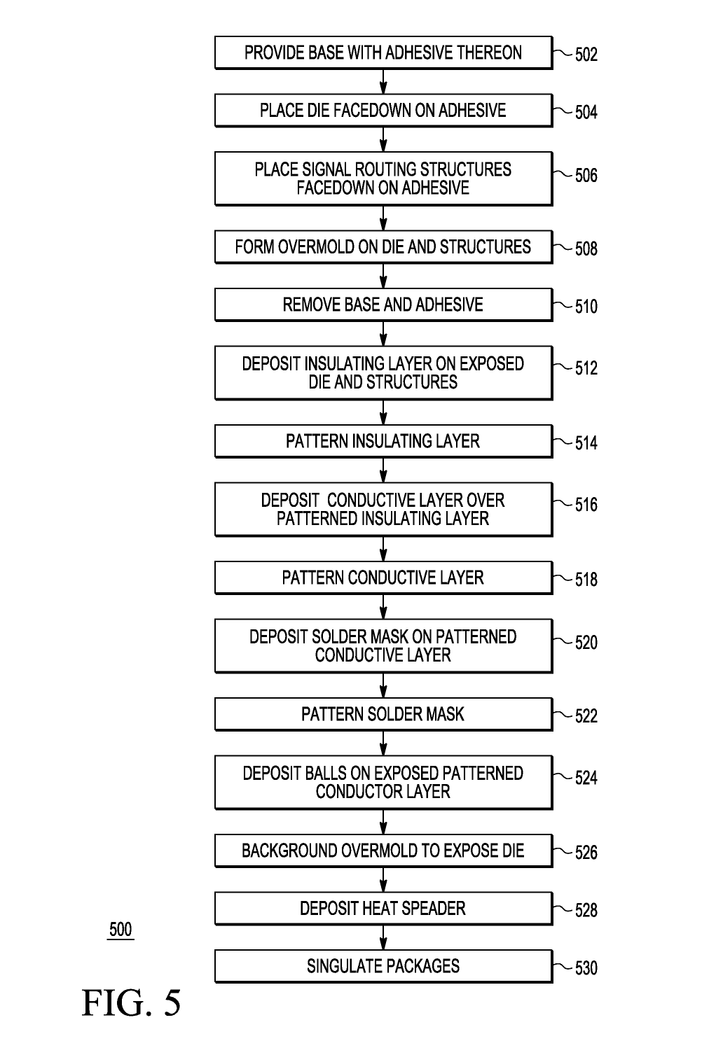

FIG. 5 is a flow chart showing an example of a manufacturing process 500 used to assemble a BGA package consistent with various embodiments of the present invention, such as package 100, although it should be appreciated that there are many other variations.

As shown in FIG. 5, the assembly process begins at step 502, where a re-usable base, such as circular plate or a rectangular panel of metal, ceramic, or other suitable material, is provided. The base is substantially flat and, on the flat surface, a layer of adhesive is deposited. The adhesive layer might be a double-sided tape or the like. The adhesive layer is preferably a type of adhesive that “releases” or loses its adhesive quality when heated above a known temperature.

Next, in step 504, the die 102 (FIG. 2) is placed with the die pads 104 on the die facing the adhesive layer. In step 506, the signal-routing structure 108 is placed so that the contact pads 110, 114 on the front surface of the structure 108 face the adhesive layer. A conventional “pick and place” technique might be used to place the die and signal-routing structure on the adhesive layer. In an alternative embodiment, step 506 is performed before step 504 or the steps are performed concurrently.

After the dies 102 and signal-routing structure 108 are placed on the adhesive layer, in step 508, the epoxy overmold 118 is deposited by, for example, applying the molding compound is using a mold insert of a conventional injection-molding process, as is known in the art. The molding material is typically applied as a liquid polymer, which is then cured by heating and/or exposure to UV light to form a solid. The molding material can also be a solid that is heated to form a liquid for application and then cooled to form a solid mold. Subsequently, an oven might be used to cure the molding material to complete the cross linking of the polymer. In alternative embodiments, other encapsulating processes may be used.

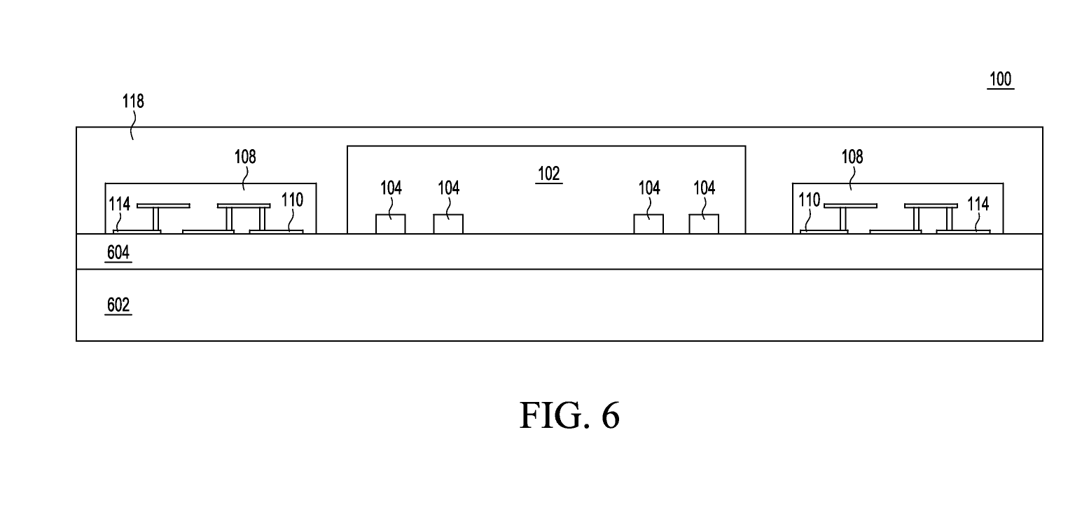

FIG. 6 shows a cross-sectional side view of a partially formed package 100 after the epoxy overmold 118 is deposited and cured in step 508. It is understood that, while only one die 102 and a signal-routing structure 108 are shown, what is shown is part of a larger structure having multiple dies and signal-routing structures that will eventually be separated (singulated) into individual BGA packages and will be referred to herein as either a singular package or multiple packages before singulation. As shown here, the reusable base 602 is shown with the adhesive layer 604 thereon, with one die 102 and two portions of the structure 108 stuck to the adhesive layer. The epoxy overmold 118 is shown over the die 102 and structure 108.

Returning to FIG. 5, in step 510, the partially formed package 100 is heated so that the adhesive layer 604 (FIG. 6) detaches from the die 102, signal-routing structure 108, and overmold 118, and the base might be readied for reuse. The detaching of the adhesive layer 604 reveals the die pads 104 and the first and second sets of contact pads 110, 114 on the die 102 and signal-routing structure 108, respectively.

In step 512, an optional insulating layer 120 (FIG. 2) of polyimide or the like is deposited by spinning the partially completed packages 100 and depositing liquid (uncured) polyimide to form a layer on the spinning packages 100, and then allowing the polyimide to cure. The cured polyimide insulating layer is then patterned in step 514 to expose the contact pads 110, 114 and die pads 104.

In step 516, a conductive layer, such as copper or a copper alloy, is deposited by sputtering or plating the metal onto the patterned insulating layer. In an alternative embodiment where the optional insulating layer 120 is not deposited, steps 512 and 514 are skipped, and the conductive layer is deposited directly onto the exposed die 102 and structure 108. Then, in step 518, the metal layer is patterned to form the traces 124 and connection pads 126 (FIG. 2).

After the traces 124 and pads 126 are formed, in step 520, a solder mask 128 (FIG. 2) is deposited using, for example, the above-described spin-on technique, and, in step 522, the solder mask is patterned, e.g., photolithographically, to expose the connection pads 126.

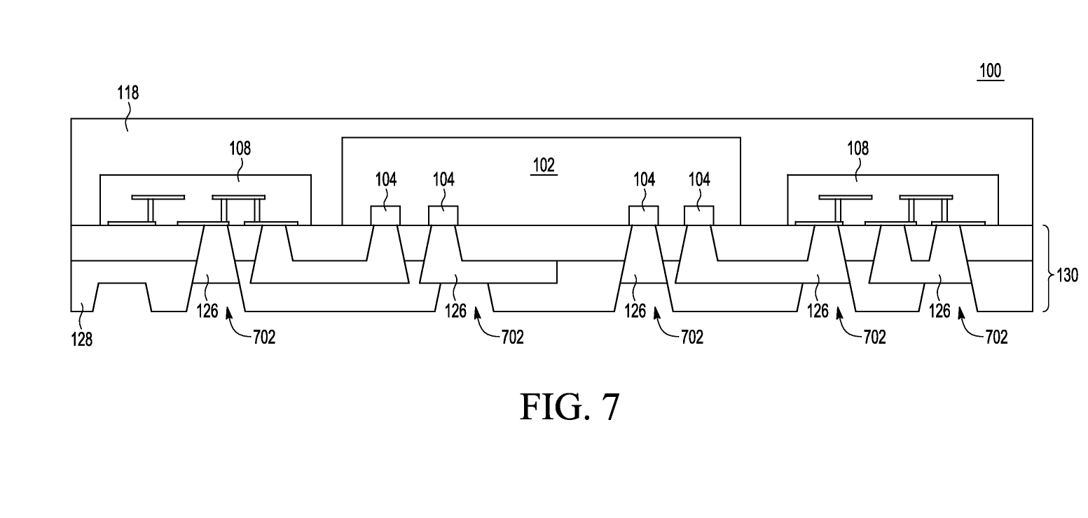

FIG. 7 shows a cross-sectional side view of the partially completed package 100 with the openings 702 in the solder mask layer 128 exposing the connection pads 126 and completing the substrate 130.

Returning to FIG. 5, in step 524, solder balls 132, 134 (FIGS. 2 and 3) are deposited on the exposed connection pads 126 by any one of a variety of known techniques, such as ball drop, screen-printing, or plating.

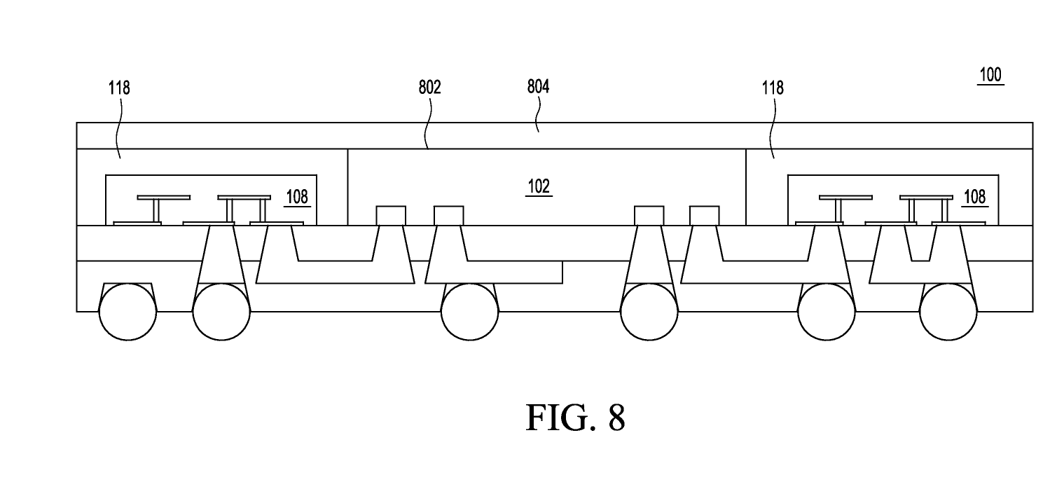

If a heat spreader is to be attached to the package 100, then, in step 526, the overmold 118 is ground down, using well-known techniques such as backgrinding, to expose the backside of the die 102. Then, in step 528, a heat spreader such as copper or a copper alloy, aluminum, or other suitable heat-conducting material is deposited on the package 100 and in contact with the exposed backside of the die 102. This is illustrated in FIG. 8, where the package 100 is shown with the overmold 118 ground down to expose backside 802 of the die 102 and the heat-conductive heat spreader 804 attached thereto. If no heat spreader is to be added, then steps 526 and 528 are skipped.

In either case, in step 530, the packages 100 are singulated into individual packages using a saw or laser to create individual instantiations of BGA package 100.

At this point, the singulated BGA package 100 can be attached to a printed wiring board or other device (not shown) using a process such as thermo-compression bonding of the balls 132 and 134 disposed on the bottom surface of package 100 to the printed wiring board.

In a conventional BGA package having a substrate that connects die pads to an array of solder balls of increased pitch, the lateral dimensions of the package are often dictated by the minimum pitch of the solder balls, while the thickness of the package is often dictated by the thickness of the substrate, which must provide distinct conductive paths between corresponding die pads and solder balls. In such a conventional BGA package, the lateral dimensions of a centrally positioned, rectangular die are smaller than those of the substrate.

The present invention takes advantage of the resulting “unused” space that exists on all four sides of the die in a conventional BGA package by migrating some of the routing resources from the substrate to one or more signal-routing structures located adjacent to the die above the substrate. As such, the substrate, located below the die and the one or more signal-routing structures, has fewer routing resources to provide and can therefore be thinner and have smaller lateral dimensions than an analogous conventional substrate. As a result, a BGA package of the present invention can be thinner than an analogous conventional BGA package.

Although embodiments of the invention are described herein as including only a single IC die disposed within a BGA package, in alternative embodiments, multiple semiconductor dies are disposed within a single package, wherein at least some of the electrical connections between one or more of the dies and the balls pass through connections in a signal-routing structure.

By now, it should be appreciated that there has been provided an improved BGA package and a method of forming the improved BGA package. Circuit details are not disclosed because knowledge thereof is not required for a complete understanding of the invention.

Although the invention has been described using relative terms such as “front,” “back,” “top,” “bottom,” “over,” “above,” “under” and the like in the description and in the claims, such terms are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Unless stated otherwise, terms such as “first” and “second” are used to arbitrarily distinguish between the elements such terms describe. Thus, these terms are not necessarily intended to indicate temporal or other prioritization of such elements. Further, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

As used herein, the term “mount,” as in “a component mounted on a substrate” or a step of “mounting a component on a substrate,” covers situations in which the component is mounted directly onto the substrate with no other intervening components or structures, as well as situations in which the active component is directly mounted to one or more other components and/or structures, which are, in turn, directly mounted to the substrate.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

It should be understood that the steps of the exemplary methods set forth herein are not necessarily required to be performed in the order described, and the order of the steps of such methods should be understood to be merely exemplary. Likewise, additional steps may be included in such methods, and certain steps may be omitted or combined, in methods consistent with various embodiments of the invention.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation”.

The embodiments covered by the claims in this application are limited to embodiments that (1) are enabled by this specification and (2) correspond to statutory subject matter. Non-enabled embodiments and embodiments that correspond to non-statutory subject matter are explicitly disclaimed even if they fall within the scope of the claims.

1. A semiconductor package, comprising:
a substrate;
a die mounted on a first side of the substrate;
an array of solder balls mounted on a second side of the substrate; and
a signal-routing structure mounted on the first side of the substrate and adjacent to the die, wherein the substrate and the signal-routing structure provide electrical connections between die pads on the die and some of the solder balls.

2. The semiconductor package of claim 1, wherein a first electrical connection from a first die pad to a first solder ball comprises (i) a first set of routing elements in the substrate connected to (ii) a first set of routing elements in the signal-routing structure connected to (iii) a second set of routing elements in the substrate.

3. The semiconductor package of claim 2, wherein a second electrical connection from a second die pad to a second solder ball comprises only a third set of routing elements in the substrate.

4. The semiconductor package of claim 1, further comprising one or more other signal-routing structures mounted on the substrate adjacent to the die, wherein the substrate and each other signal-routing structure provide electrical connections between other die pads of the die and other solder balls.

5. The semiconductor package of claim 1, wherein the signal-routing structure surrounds the die.

6. A semiconductor package, comprising:
a semiconductor die having at least a first set of die pads on a front side thereof;
a signal-routing structure having first and second sets of contact pads on a first surface thereof and disposed adjacent the semiconductor die, the first set of contact pads electrically interconnected to corresponding pads of the second set of contact pads;
a plurality of traces, a first set of which electrically interconnect the first set of die pads and the first set of contact pads, and a second set of which form connection pads that are electrically connected to the second set of contact pads;
a solder mask disposed over the plurality of co-planar traces and having openings to expose the connection pads; and
solder balls disposed on the exposed connection pads.

7. The semiconductor package of claim 6, wherein the die has a second set of die pads on the front side thereof, and wherein a third set of the plurality of co-planar traces form connection pads that are electrically connected to the second set of die pads.

8. The semiconductor package of claim 6, wherein the signal-routing structure comprises:
a first wiring layer and a second wiring layer above the first wiring layer;
a dielectric layer disposed between the first and second wiring layers; and
conductive vias, disposed in the dielectric layer, configured to electrically interconnect the first and second wiring layers;
wherein the contact pads are formed from the first wiring layer and the first wiring layer is formed on the first surface of the signal-routing structure.

9. The semiconductor package of claim 6, further comprising an overmold encapsulating the die and the signal-routing structure thereby forming an encapsulated structure, the semiconductor package further comprising an insulating layer disposed between the encapsulated structure and the plurality of co-planar traces.

10. The semiconductor package of claim 6, further comprising additional signal-routing structures, each additional signal-routing structure having contacts thereon and disposed adjacent to a side of the die, the contact pads electrically connected to the die pads by the plurality of traces.

11. The semiconductor package of claim 6, wherein the die has a backside, and the semiconductor package further comprises a heat spreader attached to the backside of the die.

12. A method for manufacturing a semiconductor package, the method comprising:
a) forming a signal-routing structure having first and second sets of contact pads on a first surface thereof, the first set of contact pads electrically interconnected to corresponding pads of the second set of contact pads;
b) mounting, on a base, a semiconductor die having first and second sets of die pads on a front side thereof such that the front side faces the base;
c) mounting, on the base, the signal-routing structure adjacent the semiconductor die such that the first surface of the signal-routing structure faces the substrate;
d) encapsulating the signal-routing structure and the semiconductor die;
e) detaching the encapsulated die and signal-routing structure from the base, thereby exposing the front side of the die and the first surface of the signal-routing structure; and
f) forming a substrate on the exposed front side of the die and the first surface of the signal-routing structure.

13. The method of claim 12, further comprising, before the die mounting step:
depositing a thermo-release adhesive layer on the substrate, wherein the die and the signal-routing structure are attached to the substrate in steps b) and c) with the thermo-release adhesive layer, and
step e) comprises:
applying heat to detach the encapsulated die and signal-routing structure from the substrate.

14. The method of claim 12, wherein the forming a substrate step comprises:
depositing a conductive layer over the detached encapsulated die and signal-routing structure;
patterning the conductive layer to form a plurality of co-planar traces, a first set of which electrically interconnect the first set of die pads and the first set of contact pads, and a second set of which form connection pads that are electrically connected to the second set of contact pads;
depositing a solder mask over the plurality of co-planar traces;
forming openings in the solder mask to expose the connection pads; and
depositing conductive balls on the exposed connection pads.

15. The method of claim 14, wherein:
the die has a second set of die pads on the front surface thereof, and
in the patterning step, the conductive layer is additionally patterned to form connection pads that are electrically connected to the second set of die pads.

16. The method of claim 12, wherein step a) comprises:
providing a dielectric layer;
depositing a first conductive layer on the dielectric layer to form the first surface of the signal-routing structure;
depositing a second conductive layer on the dielectric layer opposite the first conductive layer;
patterning the first conductive layer to form a first wiring layer and the first and second set of contact pads;
patterning the second conductive layer to form a second wiring layer; and
forming conductive vias in the dielectric layer, the conductive vias configured to electrically interconnect the first and second wiring layers.

17. The method of claim 12, further comprising before step f):
depositing an insulating layer on the detached encapsulated die and signal-routing structure; and
patterning the insulating layer to form openings therein, thereby exposing the first and second sets of contact pads and the die pads;
wherein the conductive layer disposed in step f) is on the insulating layer and in contact with the exposed contact pads and die pads.

18. The method of claim 12, wherein, in step c), a plurality of signal-routing structures is mounted, each structure disposed adjacent to a minor side of the die.

19. The method of claim 18, wherein the balls are substantially co-planar and most of the balls are arranged beneath each signal-routing structure.

20. The method of claim 12, further comprising:
backgrinding the detached encapsulated die and signal-routing structure to expose a backside of the die; and
attaching a heat spreader to the exposed backside of the die.
